(19) United States
(12) Patent Application Publication
(10) Pub. No.: US 2019/0311910 A1
(43) Pub. Date: Oct. 10, 2019

(54) METHOD OF POLISHING SiC SUBSTRATE

(71) Applicant: DISCO CORPORATION, Tokyo (JP)

(72) Inventors: Katsuyoshi KOJIMA, Tokyo (JP); Norihisa ARIFUKU, Tokyo (JP); Takeshi SATO, Tokyo (JP)

(21) Appl. No.: 16/372,649

(22) Filed: Apr. 2, 2019

(30) Foreign Application Priority Data
Apr. 5, 2018 (JP) 2018-073212

(51) Int. Cl. H01L 21/306

(52) U.S. Cl. CPC H01L 21/30625; H01L 29/1608

(57) ABSTRACT

A method of polishing an SiC substrate in contact with a polishing pad containing abrasive grains includes the steps of polishing the SiC substrate while supplying an acid polishing liquid to an area where the SiC substrate and the polishing pad contact each other, and thereafter, polishing the SiC substrate while supplying only water to the area while stopping supplying the acid polishing liquid.

### BACKGROUND OF THE INVENTION

### Field of the Invention

The present invention relates to a method of polishing an SiC substrate.

### Description of the Related Art

Power electronics apparatuses such as inverters and so on incorporate semiconductor elements called power devices suitable for controlling electric power. Power devices are fabricated using substrates made of single-crystal SiC (silicon carbide) (hereinafter referred to as “SiC substrates”) that are more favorable for higher withstand voltages and lower losses than single-crystal Si (silicon).

For fabricating power devices using an SiC substrate, a face side of the SiC substrate is polished by a method such as chemical mechanical polishing (CMP) or the like until it is sufficiently planarized. In recent years, there has been proposed a polishing technology that uses a polishing pad containing abrasive grains and a polishing liquid with oxidizing power for increasing an efficiency with which to polish SiC substrates, i.e., a polishing efficiency (see, for example, Japanese Patent Laid-Open No. 2008-68390).

### SUMMARY OF THE INVENTION

However, the proposed polishing technology that uses a polishing pad containing abrasive grains and a polishing liquid with oxidizing power may not necessarily achieve the level of planarity for SiC substrates that is suitable for the fabrication of power devices. Therefore, there have been demands in the art for a method of polishing an SiC substrate, which is capable of achieving both high polishing efficiency and sufficient planarity.

It is therefore an object of the present invention to provide a method of polishing an SiC substrate, which is capable of achieving both high polishing efficiency and sufficient planarity.

In accordance with an aspect of the present invention, there is provided a method of polishing an SiC substrate in contact with a polishing pad containing abrasive grains, including the steps of polishing the SiC substrate while supplying an acid polishing liquid to an area where the SiC substrate and the polishing pad contact each other, and thereafter, polishing the SiC substrate while supplying only water to the area while stopping supplying the acid polishing liquid.

The method of polishing an SiC substrate according to the aspect of the present invention includes the step (first polishing step) of polishing the SiC substrate while supplying the acid polishing liquid to the area where the SiC substrate and the polishing pad contact each other, and the step (second polishing step) of, thereafter, polishing the SiC substrate while supplying only water to the area while stopping supplying the acid polishing liquid. In the first polishing step, since the SiC substrate is polished while the acid polishing liquid is being supplied to the SiC substrate, the SiC substrate is modified by the action of the acid polishing liquid, resulting in high polishing efficiency.

In the second polishing step subsequent to the first polishing step, as only the water is supplied while stopping supplying the acid polishing liquid, the SiC substrate is prevented from being modified and achieves sufficient planarity. Consequently, the method of polishing an SiC substrate according to the aspect of the present invention is capable of achieving both high polishing efficiency and sufficient planarity.

The above and other objects, features and advantages of the present invention and the manner of realizing them will become more apparent, and the invention itself will best be understood from a study of the following description and appended claim with reference to the attached drawings showing a preferred embodiment of the invention.

### BRIEF DESCRIPTION OF THE DRAWING

FIG. 1 is a perspective view illustrating an SiC substrate by way of example; and

FIG. 2 is a cross-sectional view schematically illustrating the manner in which the SIC substrate is polished.

### DETAILED DESCRIPTION OF THE PREFERRED EMBODIMENT

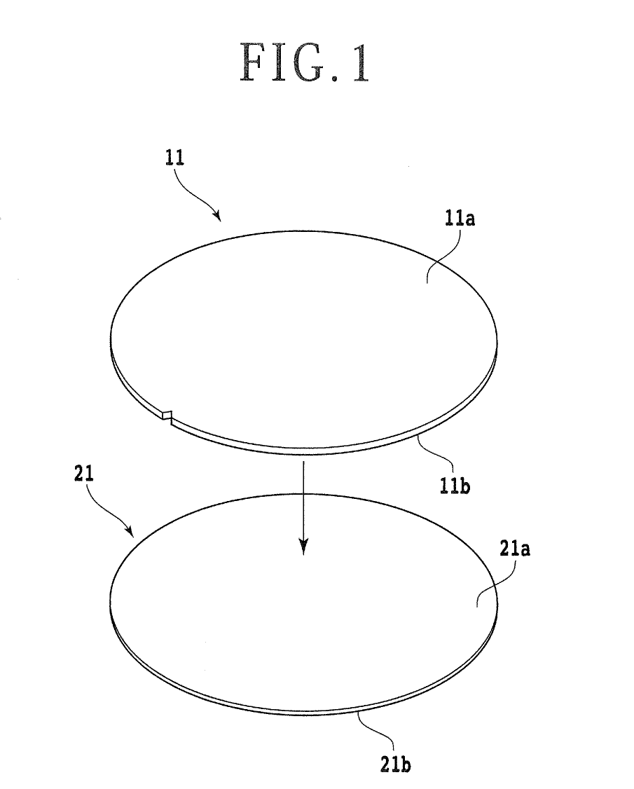

A method of polishing an SiC substrate according to an embodiment of the present invention will be described in detail below with reference to the accompanying drawings. FIG. 1 is a perspective view illustrating by way of example an SiC substrate 11 to be polished by the method according to the present embodiment. As illustrated in FIG. 1, the SiC substrate 11 is a disk-shaped wafer made of single-crystal SiC (silicon carbide) and has a first face 11a and a second face lib opposite the first face 11a. The first face 11a and the second face 11b are generally flat and lie parallel to each other.

According to the present embodiment, a protective member 21 is stuck to the second face lib of the SiC substrate 11 (protective member sticking step). The protective member 21 is a film made of a material such as resin or the like, for example, and having a circular shape slightly larger than the SiC substrate 11. The protective member 21 has a first face 21a that exhibits adhesive power with respect to the SiC substrate 11 and a second face 21b that is opposite the first face 21a.

The adhesive power of the first face 21a is realized by an adhesive or glue, for example. However, the protective member 21 is not limited to any materials, shapes, structures, etc. A substrate or the like made of a material such as semiconductor, metal, resin, or ceramics, for example, may be used as the protective member 21.

As illustrated in FIG. 1, the second face 11b of the SiC substrate 11 is protected by the protective member 21 that is stuck to the second face lib when the first face 21a of the protective member 21 is held in contact with the second face lib of the SiC substrate 11. If there is no need to protect the second face 11b of the SiC substrate 11, the protective member sticking step may be omitted.

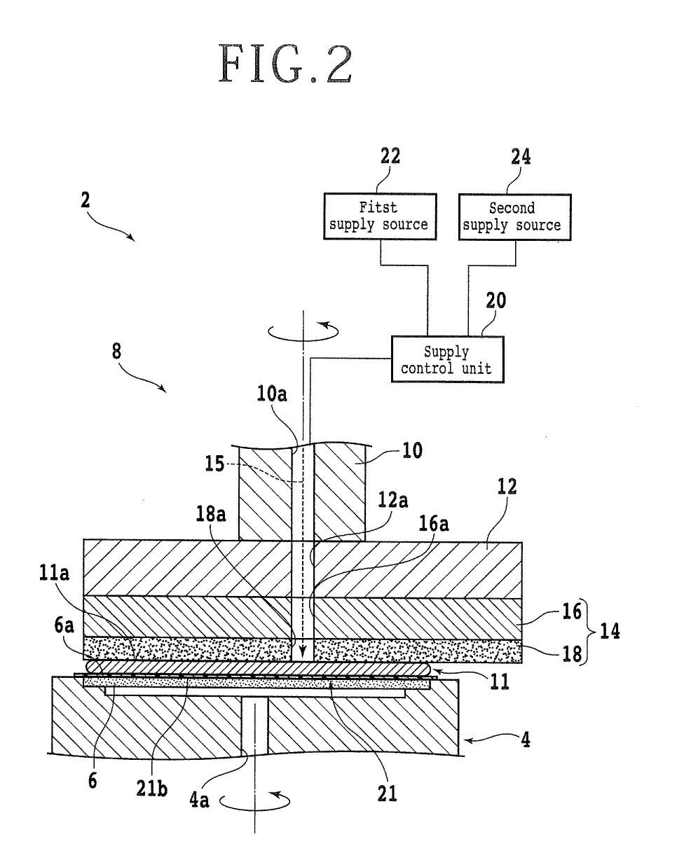

After the protective member 21 has been stuck to the SiC substrate 11, the first face 11a of the SiC substrate 11 is polished. FIG. 2 is a cross-sectional view schematically illustrating the manner in which the SiC substrate 11 is polished. According to the present embodiment, as illustrated in FIG. 2, the SiC substrate 11 is polished using a polishing apparatus 2. In FIG. 2, some components of the polishing apparatus 2 are illustrated as functional blocks.

The polishing apparatus 2 includes a chuck table 4 for holding the SiC substrate 11 thereon. The chuck table 4 is formed in a disk shape of a metal material typified by stainless steel. The polishing apparatus 2 also includes a holding plate 6 having a porous structure disposed on the chuck table 4. The holding plate 6 has an upper surface functioning as a holding surface 6a for sucking and holding the SiC substrate 11.

The holding plate 6 has a lower surface connected to a suction source, not depicted, through a flow channel 4a defined in the chuck table 4 and a valve, not depicted. When the valve is opened, a negative pressure from the suction source acts on the holding surface 6a.

The chuck table 4 is coupled to a rotary actuator, not depicted, such as an electric motor or the like, and hence can be rotated thereby about an axis that is generally perpendicular to the holding surface 6a. The chuck table 4 is supported by a moving mechanism, not depicted, and can be moved in directions generally parallel to the holding surface 6a.

The polishing apparatus 2 further includes a polishing unit 8 disposed above the chuck table 4 for polishing the SiC substrate 11. The polishing unit 8 has a spindle 10 functioning as a rotation axis that is generally perpendicular to the holding surface 6a. The spindle 10 is supported by a lifting and lowering mechanism, not depicted. A rotary actuator, not depicted, such as an electric motor or the like is coupled to the upper end, i.e., proximal end, of the spindle 10.

A disk-shaped mount 12 is fixed to the lower end, i.e., distal end, of the spindle 10. A polishing tool 14 that is of generally the same size as the mount 12 is mounted on the lower surface of the mount 12. The polishing tool 14 includes a disk-shaped base 16 made of a material such as metal or resin, for example, and held in contact with the mount 12, and a disk-shaped polishing pad 18 bonded to the lower surface of the base 16. The polishing pad 18 may be made of resin such as polyurethane or the like mixed with abrasive grains of diamond or silica, for example, but is not limited to any particular material.

The spindle 10, the mount 12, the base 16, and the polishing pad 18 have vertical holes 10a, 12a, 16a, and 18a defined respectively therein and extending vertically therethrough. The lower end of the vertical hole 10a and the upper end of the vertical hole 12a are joined to each other. The lower end of the vertical hole 12a and the upper end of the vertical hole 16a are joined to each other. The lower end of the vertical hole 16a and the upper end of the vertical hole 18a are joined to each other.

The upper end of the vertical hole 10a is connected through piping to a supply control unit 20. A first supply source 22 and a second supply source 24 are connected through piping to the supply control unit 20. The first supply source 22 supplies the supply control unit 20 with an acid polishing liquid which is a mixture of potassium permanganate and oxidizing inorganic salt. The second supply source 24 supplies the supply control unit 20 with water, typically pure water.

The supply control unit 20 selectively controls the liquids, i.e., the acid polishing liquid and the water, supplied respectively from the first supply source 22 and the second supply source 24 to flow downstream into the vertical hole 10a. The liquid, denoted by 15, i.e., the acid polishing liquid or the water, delivered from the supply control unit 20 into the vertical hole 10a flows downwardly through the vertical holes 10a, 12a, 16a, and 18a, and is discharged from the polishing unit 8 through the lower end of the vertical hole 18a in the polishing pad 18.

For polishing the first face 11a of the SiC substrate 11 with the polishing unit 8, the SiC substrate 11 is first held on the chuck table 4 (holding step). Specifically, the SiC substrate 11 is placed on the chuck table 4 such that the second face 21b of the protective member 21 stuck to the SiC substrate 11 is held in contact with the holding surface 6a.

Then, the valve is opened to cause the negative pressure from the suction source to act on the holding surface 6a. The SiC substrate 11 is now held under suction on the chuck table 4 through the protective member 21 while the first face 11a is being exposed upwardly.

After the SiC substrate 11 has been held on the chuck table 4, the SiC substrate 11 is polished by the polishing unit 8 while the acid polishing liquid is being supplied to the SiC substrate 11 (first polishing step). Specifically, while the acid polishing liquid supplied from the first supply source 22 is being delivered downstream into the vertical hole 10a by the supply control unit 20, the chuck table 4 and the spindle 10 are rotated relatively to each other about their own axes.

The spindle 10 is lowered to bring the lower surface of the polishing pad 18 into contact with the first face 11a of the SiC substrate 11. Since the acid polishing liquid supplied from the first supply source 22 is being delivered downstream into the vertical hole 10a and discharged from the lower end of the vertical hole 18a, an area where the SiC substrate 11 and the polishing pad 18 contact each other, hereinafter referred to as “contact area,” is supplied with the acid polishing liquid discharged from the vertical hole 18a.

The pressure under which the polishing pad 18 is pressed against the SiC substrate 11 is adjusted within a range for appropriately polishing the SiC substrate 11. The first face 11a of the SiC substrate 11 can thus be modified and polished by the acid polishing liquid. As a result, the polishing unit 8 achieves high polishing efficiency. According to the present embodiment, as the polishing pad 18 contains abrasive grains, the polishing liquid does not need to contain abrasive grains.

When a preset time, i.e., a first polishing time, has elapsed, the supply control unit 20 stops supplying the acid polishing liquid to the contact area referred to above, finishing the first polishing step. According to the present invention, it is not necessary to stop rotating the chuck table 4 and the spindle 10 at this time because the first face 11a of the SiC substrate 11 will continuously be polished.

After having stopped supplying the acid polishing liquid to the polishing area, i.e., after the first polishing step, the supply control unit 20 supplies only the water from the second supply source 24 to the contact area while stopping supplying the acid polishing liquid from the first supply source 22, polishing the SiC substrate 11 (second polishing step).

Specifically, the supply control unit 20 does not deliver the acid polishing liquid from the first supply source 22 downstream into the vertical hole 10a, but delivers the water from the second supply source 24 downstream into the vertical hole 10a. The contact area is thus supplied with the water discharged from the lower end of the vertical hole 18a in the polishing pad 18.

The pressure under which the polishing pad 18 is pressed against the SiC substrate 11 is adjusted within a range for appropriately polishing the SiC substrate 11. The first face 11a of the SiC substrate 11 can thus be polished, while being hardly modified, by the water. As a result, the planarity of the first face 11a is sufficiently increased. According to the present embodiment, as the polishing pad 18 contains abrasive grains, the polishing liquid does not need to contain abrasive grains.

When a preset time, i.e., a second polishing time, has elapsed, the second polishing step is finished. If the second polishing time is too long, then the polishing efficiency tends to be lowered. From the standpoint of keeping the polishing efficiency sufficiently high, the second polishing time should preferably be two minutes or shorter and more preferably be one minute or shorter, for example.

If the polishing efficiency can be kept sufficiently high in connection with the first polishing step, then the second polishing time may be longer than two minutes. For example, if the second polishing time is one-fifth of the first polishing time or shorter, or preferably one-tenth of the first polishing time or shorter, then the polishing efficiency is less liable to decrease even if the second polishing time is longer than two minutes.

An experiment conducted to confirm the effectiveness of the method of polishing an SiC substrate according to the present embodiment will be described below. In the experiment, SiC substrates were polished by the polishing method according to the present embodiment selectively using the acid polishing liquid and the water and by the existing polishing method using only an acid polishing liquid, and polished depths, polishing rates, and levels of surface roughness (arithmetical mean roughness Ra) were compared with each other.

Conditions including the rotational speed (500 rpm) of the chuck table, the rotational speed (495 rpm) of the spindle or the polishing pad, the pressure (73.5 kpa) under which the polishing pad is pressed against the SiC substrate, the flow rate (150 mL/min) of the liquid used for polishing the SiC substrate, the polishing time (six minutes), etc. were common in the polishing method according to the present embodiment and the existing polishing method.

Specifically, in the polishing method according to the present embodiment, the acid polishing liquid was supplied at the flow rate of 150 mL/min in the first polishing step, and the water was supplied at the flow rate of 150 mL/min in the second polishing step. In the polishing method according to the present embodiment, furthermore, the time for which the first polishing step lasted, i.e., the first polishing time, was five minutes, and the time for which the second polishing step lasted, i.e., the second polishing time, was one minute.

The results of the experiment are depicted in Table 1 below. As can be seen from Table 1, the polished depths and the polishing rates in the polishing method according to the present embodiment and the existing polishing method were not significantly different from each other, and both polishing methods obtain high polishing efficiency. In the polishing method according to the present embodiment, however, the level of surface roughness of the polished SiC substrate increased to a large extent compared with the level of surface roughness achieved by the existing polishing method. It can be confirmed that the polishing method according to the present embodiment is capable of achieving both high polishing efficiency and sufficient planarity.

TABLE 1

| | Polished depth | Polishing rate | Surface roughness |
|---|---|---|---|
| | (μm) | (μm/h) | (nm) |
| Present embodiment | 2.3 | 22.8 | 0.359 |
| Existing method | 2.4 | 23.8 | 0.506 |

As described above, the method of polishing an SiC substrate according to the present embodiment includes the first polishing step of polishing the SiC substrate 11 while supplying the acid polishing liquid to the SiC substrate 11, and the second polishing step of polishing the SiC substrate 11 while supplying only the water to the SiC substrate 11 while stopping supplying the acid polishing liquid.

In the first polishing step, since the SiC substrate 11 is polished while the acid polishing liquid is being supplied to the SiC substrate 11, the SiC substrate 11 is modified by the action of the acid polishing liquid, resulting in high polishing efficiency. In the second polishing step subsequent to the first polishing step, as only the water is supplied while stopping supplying the acid polishing liquid, the SiC substrate 11 is prevented from being modified and achieves sufficient planarity.

The present invention is not limited to the present embodiment described above, but various changes and modifications may be made within the scope of the invention. For example, though the second polishing step is carried out consecutively to the first polishing step in the above embodiment, it is not necessary to carry out the second polishing step consecutively to the first polishing step.

In the second polishing step according to the present embodiment, the SiC substrate 11 is polished while only the water is being supplied thereto. The second polishing step does not necessarily mean that the SiC substrate 11 is polished by only the water. The acid polishing liquid that remains on the polishing pad 18, etc. from the first polishing step may possibly slightly act on the SiC substrate 11 in the second polishing step.

The structure, method, and other details according to the present embodiment may be changed or modified without departing from the scope of the invention.

The present invention is not limited to the details of the above described preferred embodiment. The scope of the invention is defined by the appended claim and all changes and modifications as fall within the equivalence of the scope of the claim are therefore to be embraced by the invention.

What is claimed is:

1. A method of polishing an SiC substrate in contact with a polishing pad containing abrasive grains, comprising the steps of:
polishing the SiC substrate while supplying an acid polishing liquid to an area where the SiC substrate and the polishing pad contact each other; and
thereafter, polishing the SiC substrate while supplying only water to the area while stopping supplying the acid polishing liquid.
